(19) United States
(12) Patent Application Publication
(10) Pub. No.: US 2002/0168029 A1
(43) Pub. Date: Nov. 14, 2002

(54) Digital signal receiving apparatus

(75) Inventors: Kazuhiro Onizuka, Tokyo (JP); Shin Ito, Yokohama-shi (JP); Kenichi Tanimoto, Yokohama-shi (JP); Keiji Yamahai, Yokohama-shi (JP)

Correspondence Address: GREENBLUM & BERNSTEIN, P.L.C., 1941 ROLAND CLARKE PLACE, RESTON, VA, 20191, US

(73) Assignee: MATSUSHITA ELECTRIC INDUSTRIAL CO. LTD, Osaka (JP)

(21) Appl. No.: 10/137,381

(22) Filed: May 3, 2002

(30) Foreign Application Priority Data
May 10, 2001 (JP) 2001-140610

(51) Int. Cl. H03K 9/00

(52) U.S. Cl. 375/316

(57) ABSTRACT

A digital signal receiving apparatus which can automatically determine the transmission format of a digital audio signal based on AES3, and then simplify the operations, avoid wrong operations at times of switching, and prevent errors in the transmission format due to wrong operations. In this apparatus, a channel status FS detection section 109 detects the sampling frequency of an input digital audio signal based on AES3, a transmission rate detection section 111 detects the transmission rate of the input digital audio signal based on AES3. A control section 113 determines the transmission format of the input digital audio signal based on AES3, based on both detected results (sampling frequency and transmission rate).

### BACKGROUND OF THE INVENTION

1. Field of the Invention

The present invention relates to a digital signal receiving apparatus in an audio system.

2. Description of Related Art

According to AES3 which is a standard for digital audio transmission and which defines the transmission format of a digital audio signal, it is possible to transmit a digital audio signal with a sampling frequency of 44.1 kHz-96 kHz. Moreover, a quadruple sampling digital audio signal of 176.4 kHz-192 kHz can be transmitted based on AES3.

The transmission of the signals of 44.1 kHz and 48 kHz is the basis of AES3, and the transmission of high-sampling signals of 88.2-96 kHz has been additionally defined following the development of high sampling technologies. Because a high-sampling signal has twice as much information as a basic signal does, the transmission of the signal has been defined in a plurality of methods (transmission formats). A standard for quadruple sampling signals of 176.4 kHz-192 kHz is currently under study, but these can be transmitted using a double sampling format. In the present specification, the signals including the above-defined basic signals and double sampling signals in addition to the quadruple sampling signals will be called “digital audio signals based on AES3”.

Of the digital audio signals based on AES3, the double and quadruple sampling signals have the following transmission formats, as shown in the table of FIG. 1:

1) A transmission mode (hereinafter called “Single Channel Double Sampling Frequency Mode”) in which signals are transmitted at double the normal transmission rate at a double sampling frequency;

2) A transmission mode (hereinafter called “Two Channel Mode”) in which one channel of high-sampling signals are transmitted at the normal transmission rate on one signal line at a double sampling frequency, even though two channels of audio signals are normally transmitted on one signal line;

3) A transmission mode (hereinafter called “Double-Hi-speed Single Wire”) in which signals are transmitted at four times the normal transmission rate at a quadruple sampling frequency;

4) A transmission mode (hereinafter called “Double-speed Dual Wire”) in which quadruple sampling signals are transmitted at double the normal transmission rate on one single line, in which, using two of the above signal lines described above, two channels of signals are transmitted at a quadruple sampling frequency; and

5) A transmission mode (hereinafter called “Quad Wire”) in which quadruple sampling signals are transmitted at the normal transmission rate on one single line, and in which, using four of the signal lines described above, two channels of signals are transmitted at a quadruple sampling frequency.

Moreover, according to AES3, subcodes are defined in order to classify sampling frequencies, channel modes, and so on. FIG. 2 is a table showing the subcodes on the basis of AES3.

FIG. 3 is a block diagram showing a configuration of a conventional digital signal receiving apparatus. In this case, an AES/EBU signal input is received at an AES/EBU receiving section 1 and output as an audio data output after a format conversion in a format conversion section 3. At this point, the sampling frequency of a received signal is manually set in a sampling frequency manual setting section 9, and the AES/EBU receiving section 1 performs a receiving process of the signal, using a receiving clock generated in a receiving clock generation section 5. The transmission format of the received signal is manually set in an AES/EBU format manual setting section 11. A control section 13 determines the transmission format together with the sampling frequency which has been manually set in the sampling frequency manual setting section 9 and, using a sampling clock generated in a sampling clock generation section 7, makes the format conversion section 3 perform a format conversion of the signal subject to a receiving process in the AES/EBU receiving section 1. By this, audio data is output in every individual transmission format shown in FIG. 1. As described above, manual setting is required in the sampling frequency manual setting section 9 and in the AES/EBU format manual setting section 11 of the present apparatus in order to determine the transmission format of a received signal.

Moreover, in another conventional digital signal receiving apparatus, the automatic switching of a transmission format is definitely achieved by adding a unique code to the subcode of an AES/EBU signal.

However, the conventional apparatus has the following problem. Manual setting is required, as described above, in the sampling frequency manual setting section 9 and in the AES/EBU format manual setting section 11 of the present apparatus in order to determine the transmission format of a received signal. However, when, for example, high sampling transmission is performed using a Two Channel Mode transmission format, errors may not be recognized due to a setting mistake in the receiving apparatus, even though voices are still transmitted and the transmission is received in basic sampling. Another problem is that whenever there is a change in the setting at the transmission apparatus side, the setting at the receiving apparatus side also needs to be changed.

In addition, another problem is that there is no compatibility with others, as a unique subcode is used when automatic switching is performed by adding a unique code to the subcode of an AES/EBU signal.

Moreover, with the subcode information defined in AES3 alone, all sampling frequencies and transmission methods may not be determined.

### SUMMARY OF THE INVENTION

It is an object of the present invention to provide a digital signal receiving apparatus which can automatically determine the transmission format of a digital audio signal based on AES3, and then simplify the operations, avoid wrong operations at times of switching, and prevent errors in the transmission format due to wrong operations.

According to an aspect of the invention, a digital signal receiving apparatus is a digital signal receiving apparatus for receiving a digital audio signal and comprises first detection means for detecting sampling frequency of an input digital audio signal, second detection means for detecting transmission rate of the input digital audio signal, and determination means for determining transmission format of the input digital audio signal based on the sampling frequency detected by the first detection means and the transmission rate detected by the second detection means.

The above and other objects and features of the present invention will become clear from the following description of preferred embodiments with the accompanying drawings.

### BRIEF DESCRIPTION OF THE DRAWINGS

FIG. 1 is a table showing a transmission format for each sampling frequency and transmission rate according to AES3;

FIG. 2 is a view showing a table of subcodes on the basis of the AES3 standard;

FIG. 3 is a block diagram showing a configuration of a conventional digital signal receiving apparatus;

FIG. 4 is a block diagram showing a configuration of a digital signal receiving apparatus according to embodiment 1 of the present invention;

FIG. 5 is a block diagram showing a configuration of a digital signal receiving apparatus according to embodiment 2 of the present invention;

FIG. 6 is a block diagram showing a configuration of a digital signal receiving apparatus according to embodiment 3 of the present invention;

FIG. 7 is a block diagram showing a configuration of a digital signal receiving apparatus according to embodiment 4 of the present invention; and

FIG. 8 is a block diagram showing a configuration of a digital signal receiving apparatus according to embodiment 5 of the present invention.

### DESCRIPTION OF THE PREFERRED EMBODIMENT

The embodiments according to the present invention will be described in detail with the accompanying drawings.

### Embodiment 1

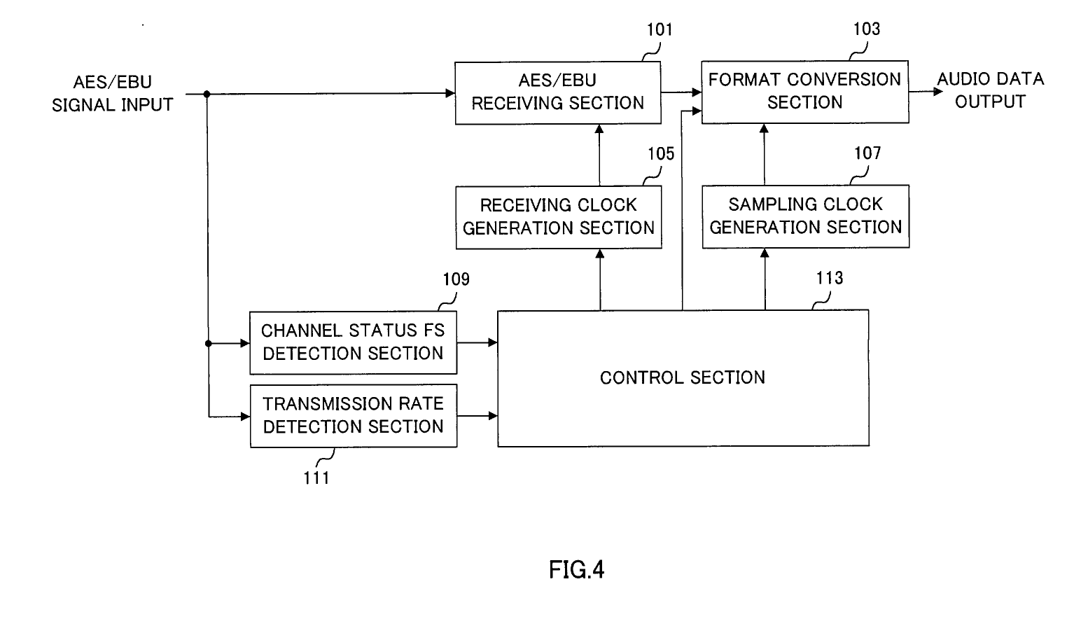

FIG. 4 is a block diagram showing a configuration of a digital signal receiving apparatus according to embodiment 1 of the present invention.

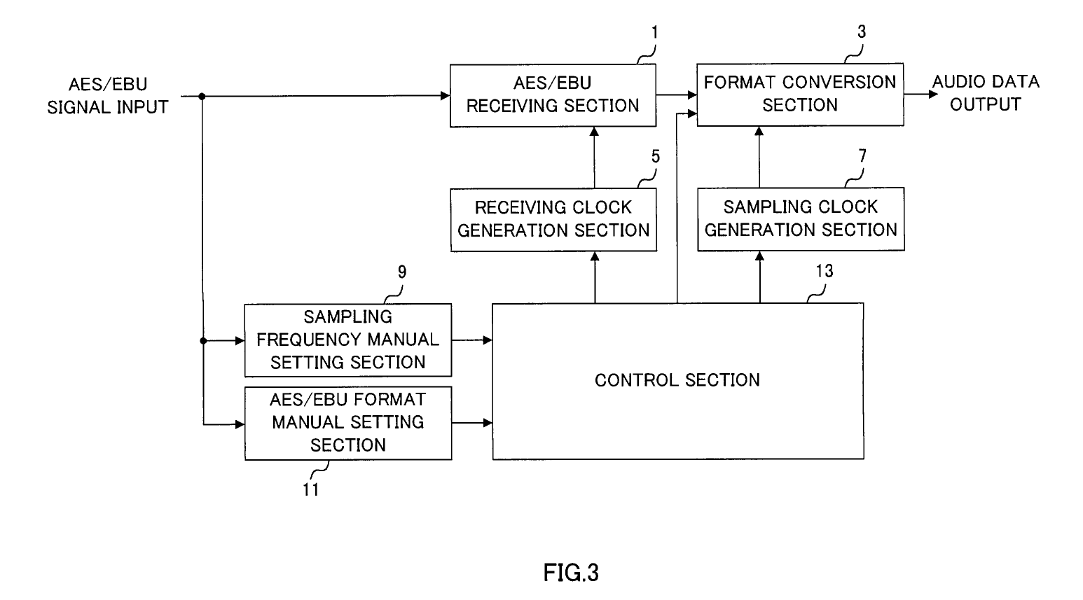

As shown in FIG. 4, this apparatus comprises an AES/EBU receiving section 101, a format conversion section 103, a receiving clock generation section 105, a sampling clock generation section 107, a channel status FS detection section 109 (first detection means), a transmission rate detection section 111 (second detection means), and a control section 113 (determination means). The AES/EBU receiving section 101, the format conversion section 103, the receiving clock generation section 105, and the sampling clock generation section 107 all correspond to the AES/EBU receiving section 1, the format conversion section 3, the receiving clock generation section 5, and the sampling clock generation section 7 in the conventional apparatus shown in FIG. 3, respectively, and, therefore, further description of these will be omitted.

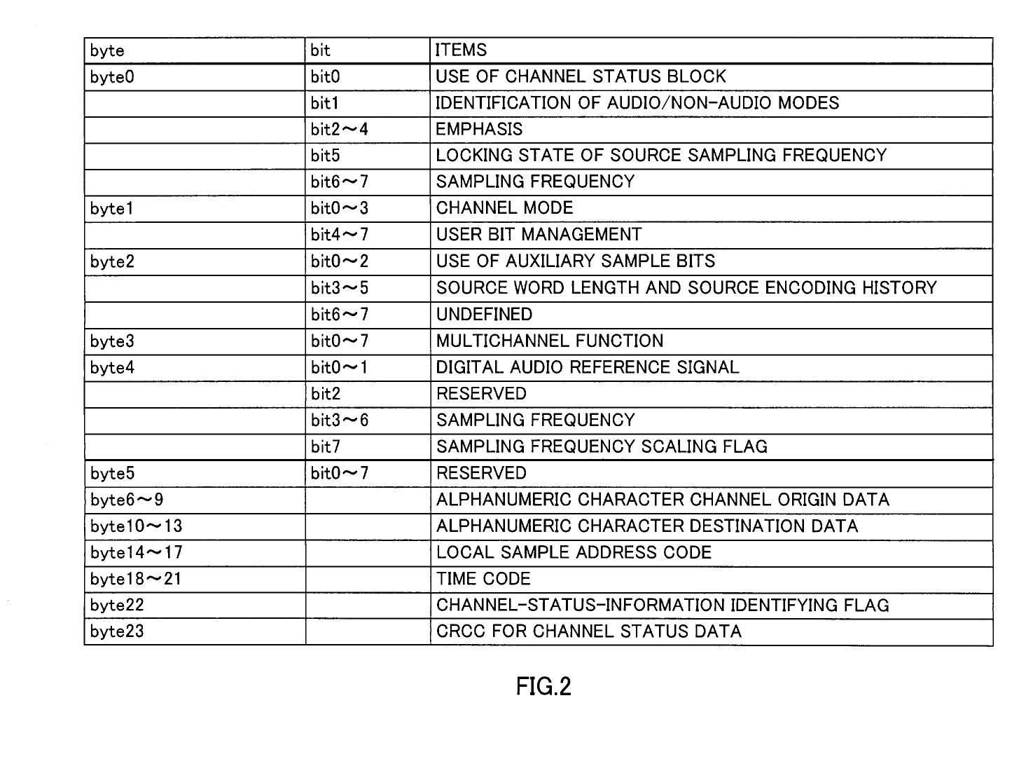

The channel status FS detection section 109 detects a subcode of an input digital audio signal based on AES3 (AES/EBU signal input) and identifies (detects), from the detected subcode, sampling frequency (FS) according to the table in FIG. 2.

The transmission rate detection section 111 determines (detects) transmission rate after detecting the cycles, for example, by counting between the preambles of an input digital audio signal based on AES3 using a clock having a predetermined frequency.

The control section 113 determines the transmission format of an input digital audio signal based on AES3, on the basis of the sampling frequency detected by the channel status FS detection section 109 and the transmission rate detected by the transmission rate detection section 111, and, at the same time, controls the format conversion section 103, the receiving clock generation section 105, and the sampling clock generation section 107.

Now, the operations of the digital signal receiving apparatus of the above configuration will be described.

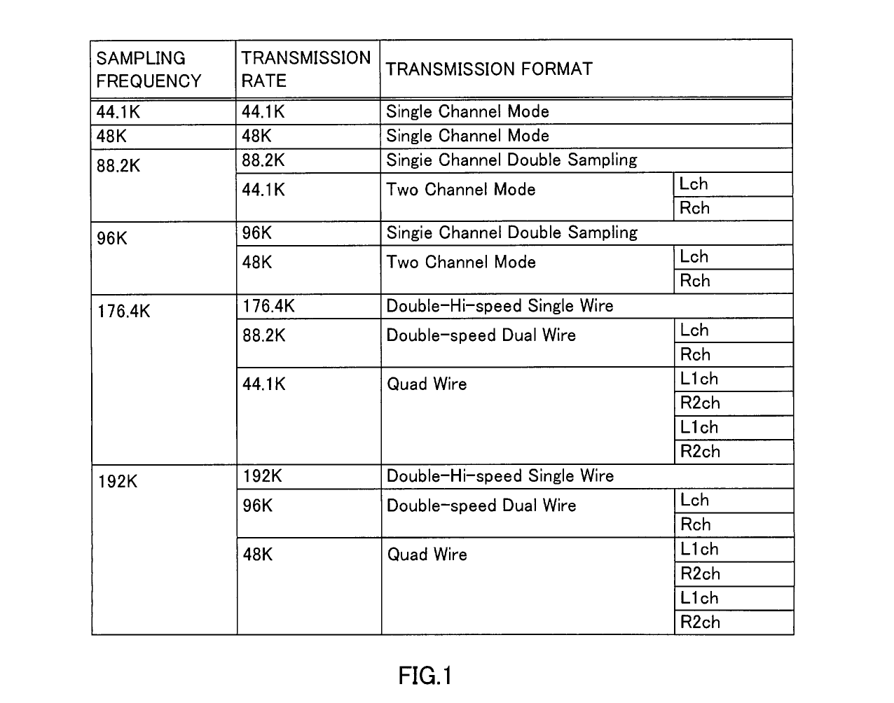

An input digital audio signal based on AES3 (AES/EBU signal input) is received at the AES/EBU receiving section 101 and is output as an audio data output after a format conversion in the format conversion section 103. At this point, the channel status FS detection section 109 detects the subcode of the input digital audio signal based on AES3, and identifies from the detected subcode the sampling frequency on the basis of the table of FIG. 2, and the AES/EBU receiving section 101 performs a receiving process of the signal, using a receiving clock generated in the receiving clock generation section 105. The transmission rate detection section 111 determines the transmission rate after detecting the cycles by counting between the preambles of input digital audio signals based on AES3 using a clock having a predetermined frequency, and the control section 113 determines the transmission format together with the sampling frequency identified in the channel status FS detection section 109, and the format conversion section 103 performs, using the sampling clock generated in the sampling clock generation section 107, a format conversion of the signal subject to a receiving process in the AES/EBU receiving section 101. Thus, a transmission format of FIG. 1 is determined upon and audio data is output.

As described above, the digital signal receiving apparatus of the present embodiment detects the sampling frequency and transmission rate of an digital audio signal based on AES3, and, on the basis of these detection results (sampling frequency and transmission rate), determines the transmission format of a inputting digital audio signal based on AES3, so that the present apparatus can automatically determine the transmission format of a digital audio signal based on AES3, and then simplify the operations, avoid wrong operations at times of switching, and prevent errors in the transmission format due to wrong operations.

### Embodiment 2

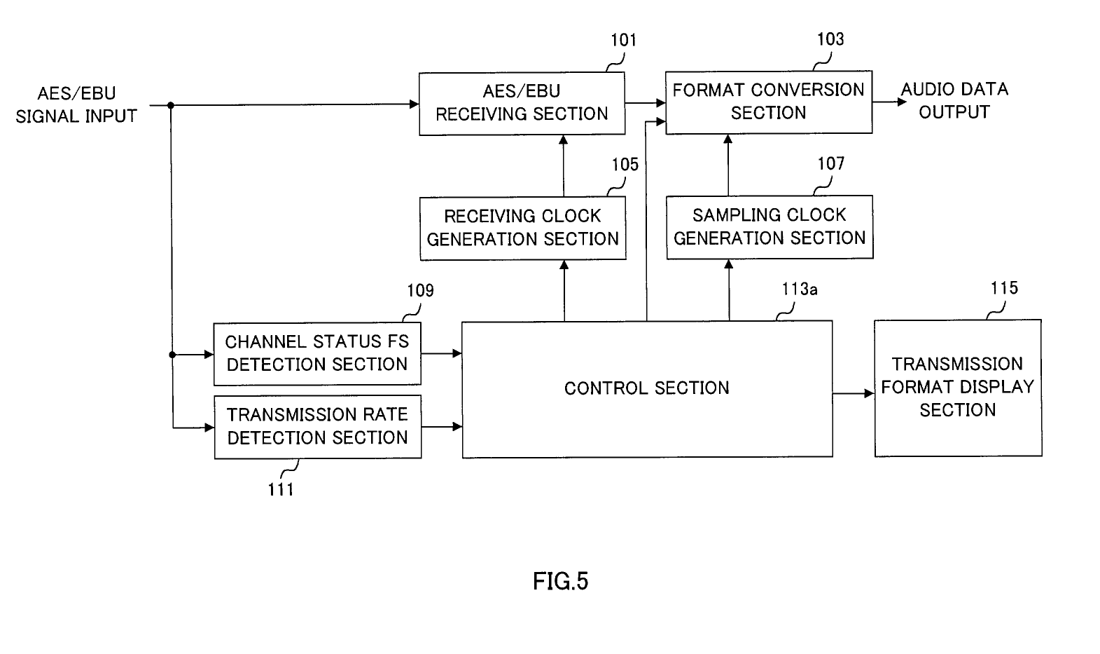

FIG. 5 is a block diagram showing a configuration of a digital signal receiving apparatus according to embodiment 2 of the present invention. Here, the digital signal receiving apparatus has a basic configuration similar to that of the digital signal receiving apparatus corresponding to embodiment 1 shown in FIG. 4. The same and equivalent components are given the same reference numbers without further description thereof.

A feature of embodiment 2 is that, in contrast to the digital signal receiving apparatus corresponding to embodiment 1 shown in FIG. 4, embodiment 2 has a transmission format display section 115. The present embodiment is the same as the digital signal receiving apparatus corresponding to embodiment 1 in all the other aspects.

The transmission format display section 115 displays a sampling frequency detected in the channel status FS detection section 109 and a transmission format determined in a control section 113a. Therefore, in the transmission format display section 115, for example, LEDs for sampling frequencies are provided for each sampling frequency, respectively, and LEDs for transmission formats are provided for each transmission format, respectively. Specifically, the transmission format display section 115 displays sampling frequencies with LEDs provided for each numerical value of 44.1 kHz, 48 kHz, 88.2 kHz, 96 kHz, 176.4 kHz, and 192 kHz, and, at the same time, displays transmission formats with LEDs installed for each type of Single Channel Mode, Two Channel Mode, QuadWire, Single Channel Double Sampling Frequency Mode, Double-speed Dual Wire, and Double-Hi-speed Single Wire.

As described above, the digital receiving apparatus of the present embodiment displays the sampling frequency (automatically detected result) as well as the transmission format (automatically determined result) of an input digital audio signal based on AES3, so that transmission formats and the like can be monitored at all times.

### Embodiment 3

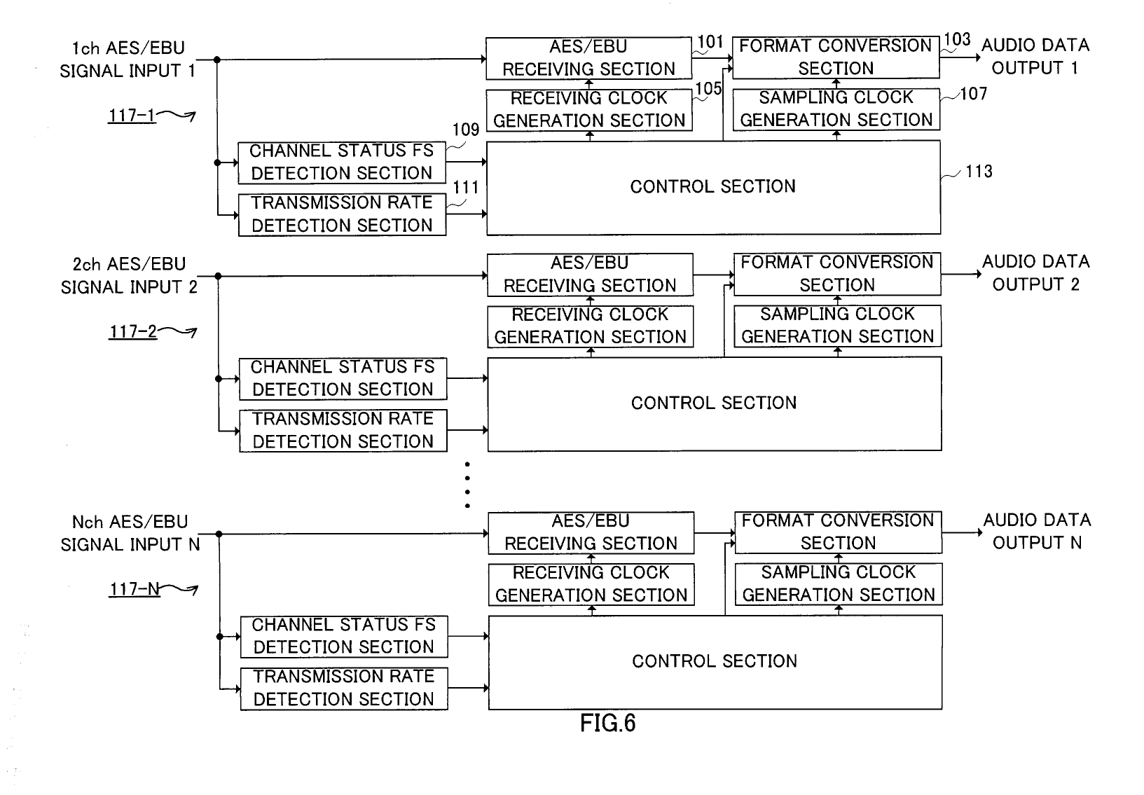

FIG. 6 is a block diagram showing a configuration of a digital signal receiving apparatus according to embodiment 3 of the present invention. Here, the digital signal receiving apparatus has a basic configuration similar to that of the digital signal receiving apparatus corresponding to embodiment 1 shown in FIG. 4. The same and equivalent components are given the same reference numbers without further description thereof.

A feature of embodiment 3 is that the digital signal receiving apparatus corresponding to embodiment 1 shown in FIG. 4 is provided with a plurality of channels respectively, each channel operable individually from all the other channels. Hereinafter, a digital signal receiving apparatus constituting such channel and corresponding to that of embodiment 1 shown in FIG. 4 will be called a “digital signal receiving unit”.

The digital signal receiving apparatus shown in FIG. 6 has a plurality of (herein N) channels, each having a digital signal receiving unit 117 of the configuration shown in FIG. 4. That is, a first channel (1ch) is provided with a digital signal receiving unit 117-1, a second channel (2ch) is provided with a digital signal receiving unit 117-2, and an Nth channel (Nch) is provided with a digital signal receiving unit 117-N.

As a result, with the present embodiment, Single Channel Mode transmission with four inputs for every two channels, or Two Channel Mode transmission with four inputs for every one channel become possible, when for example the apparatus has eight channels (N=8). Moreover, as to individual operation, a ½ channel can be used in a Single Channel Double Sampling Frequency Mode, and a ¾ channel can be used in a Two Channel Mode.

As described above, according to the digital receiving apparatus of the present embodiment, signals in different transmission formats can be simultaneously received, since a plurality of channels are provided and each channel can be operated individually.

### Embodiment 4

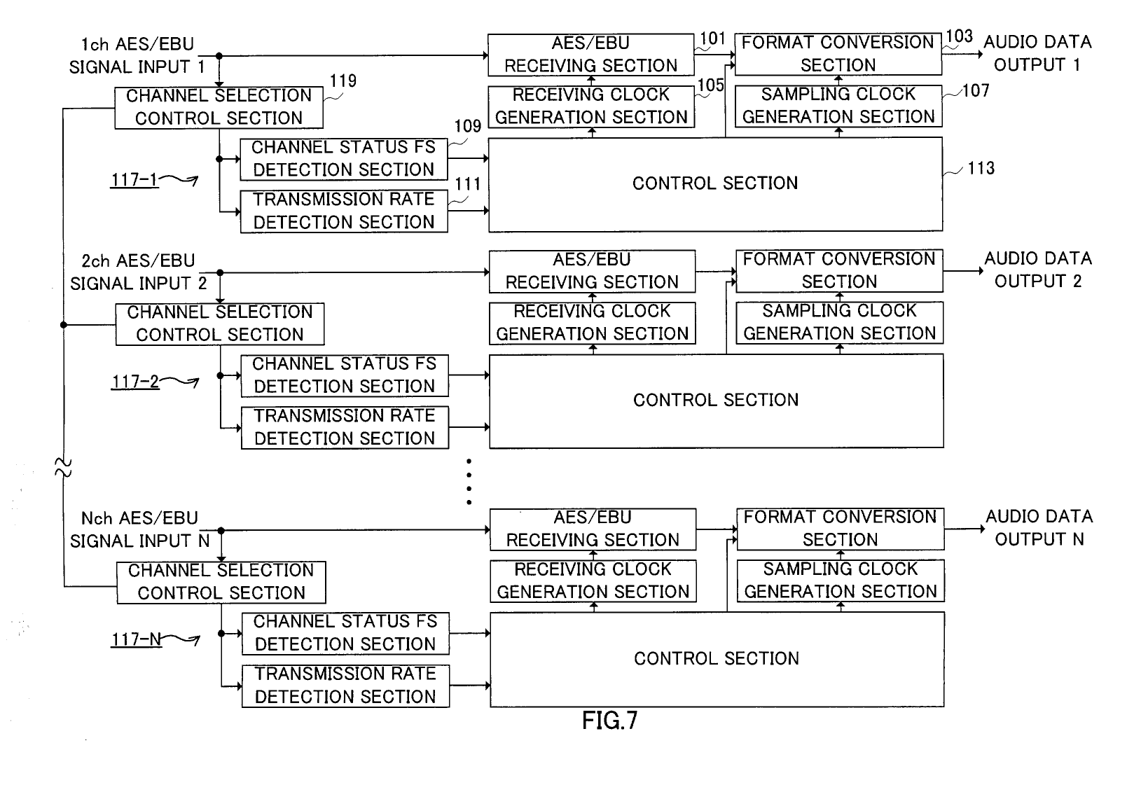

FIG. 7 is a block diagram showing a configuration of a digital signal receiving apparatus according to embodiment 4 of the present invention. Here, the digital signal receiving apparatus has a basic configuration similar to that of a digital signal receiving apparatus corresponding to embodiment 3 shown in FIG. 6. The same and equivalent components are given the same reference numbers without further description thereof.

A feature of embodiment 4 is that, in contrast to embodiment 3 shown in FIG.6, each channel is provided with a selection control section 119 (selection control means). The present embodiment is the same as the digital signal receiving apparatus corresponding to embodiment 3 in all the other aspects.

The channel selection control section 119 selects one channel from a plurality (N, for example) of channels and controls all the other channels in accordance with the selected channel. Specifically, when one channel is selected by, for example, an operation input of a user, the channel selection control section 119 of the selected channel transfers the AES/EBU signal input of its own channel to the channel selection control sections 119 of all the other channels, respectively, and the channel selection control section 119 in each of all the other channels respectively inhibits the use of its own AES/EBU signal input channel, and sends the transferred AES/EBU signal input to the channel status FS detection section 109 and the transmission rate detection section 111, respectively. That is, when the transmission formats or transmission rates of a plurality of channels are switched, other channels are operated according to a specifically set channel, and all the channels are automatically switched to a uniform transmission format or transmission rate.

As a result, with the present embodiment, for example, when an MTR (multi-truck tape recorder) is connected to the present apparatus for recording, the transmission formats of all the eight channels can be adjusted to a uniform transmission format.

Thus, according to the digital signal receiving apparatus of the present embodiment, the transmission formats of all the channels can be adjusted to a uniform transmission format, since all the other channels can be operated in accordance with one channel selected from a plurality of channels.

### Embodiment 5

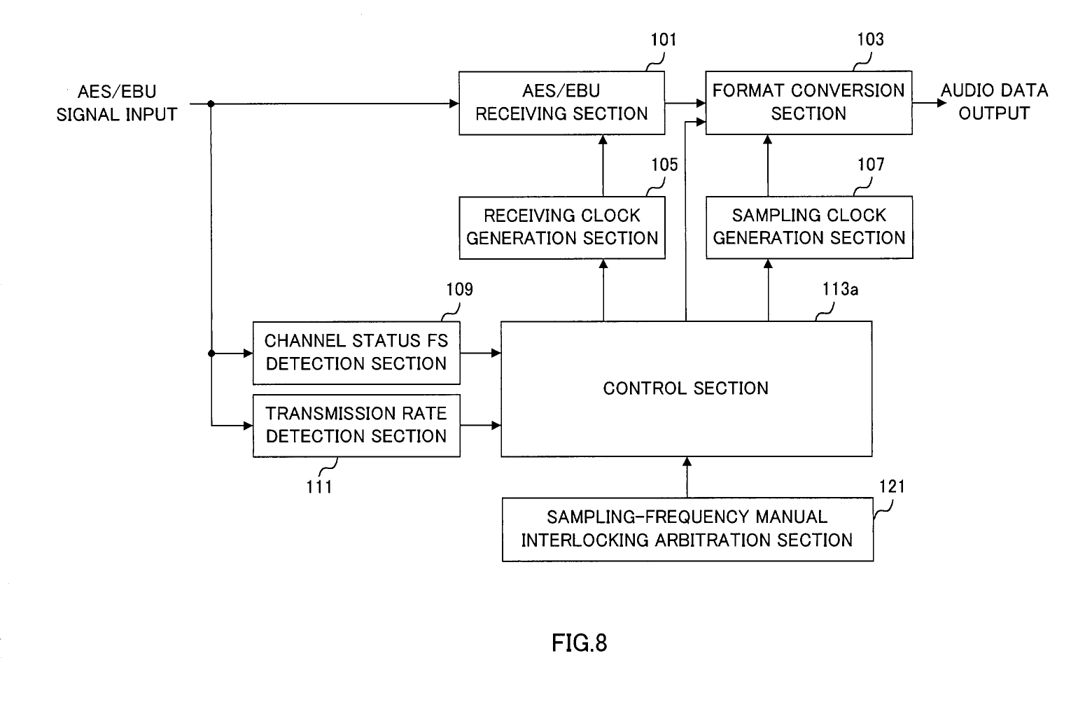

FIG. 8 is a block diagram showing a configuration of a digital signal receiving apparatus according to embodiment 5 of the present invention. Here, the digital signal receiving apparatus has a basic configuration similar to that of a digital signal receiving apparatus corresponding to embodiment 1 shown in FIG. 4. The same and equivalent components are given the same reference numbers without further description thereof.

A feature of embodiment 5 is that, in contrast to the digital signal receiving apparatuses corresponding to embodiment 1 shown in FIG. 4, a sampling-frequency manual interlocking arbitration section 121 is provided. The present embodiment is the same as the digital signal receiving apparatus corresponding to embodiment 1 in all the other aspects.

In the sampling-frequency manual interlocking arbitration section 121, the sampling frequency of an input signal can be manually switched (set).

As a result, with the present embodiment, when, for example, an error is found in the subcode of an AES/EBU signal input and the sampling frequency needs to be arbitrarily switched, the sampling frequency can be manually switched according to the last-in priority in the sampling-frequency manual interlocking arbitration section 121, for example.

As described above, the digital signal receiving apparatus of the present embodiment can manually set sampling frequency, so that, when, for example, there is an error in the subcode of an input digital audio signal based on AES3 and the sampling frequency needs to be arbitrarily switched, the present apparatus can cope with such case and manually switch the sampling frequency.

As described above, the present invention can automatically determine the transmission format of a digital audio signal based on AES3, and then simplify the operations, avoid wrong operations at times of switching, and prevent errors in the transmission format due to wrong operations.

The present invention is not limited to the above-described embodiments, and variations and modifications may be possible without departing from the scope of the present invention.

This application is based on Japanese Patent Application No. 2001-140610 filed on May 10, 2001, the entire contents of which are expressly incorporated by reference herein.

What is claimed is:

1. A digital signal receiving apparatus which receives a digital audio signal, comprising:
first detection means for detecting sampling frequency of an input digital audio signal;
second detection means for detecting transmission rate of the input digital audio signal; and
determination means for determining transmission format of the input digital audio signal, based on the sampling frequency detected by said first detection means and the transmission rate detected by said second detection means.

2. A digital signal receiving apparatus according to claim 1, further comprising display means for displaying at least one of the detection result by said first detection means, the detection result by said second detection means, and the determination result by said determination means.

3. A digital signal receiving apparatus according to claim 1, having a plurality of channels, wherein said first detection means, said second detection means, and said determination means, which are individually operable for each channel, are provided for each of the plurality of channels.

4. A digital signal receiving apparatus according to claim 1, having a plurality of channels, wherein said first detection means, said second detection means, and said determination means are provided for each of the plurality of channels, and comprising selection control means for selecting one of the plurality of channels and controlling all other channels according to the selected channel.

5. A digital signal receiving apparatus according to claim 1, comprising setting means for manually setting the sampling frequency.
